(19) United States
(12) Patent Application Publication
(10) Pub. No.: US 2015/0027529 A1
(43) Pub. Date: Jan. 29, 2015

(54) ELECTRODES FORMED BY OXIDATIVE CHEMICAL VAPOR DEPOSITION AND RELATED METHODS AND DEVICES

(71) Applicant: Massachusetts Institute of Technology, Cambridge, MA (US)

(72) Inventors: Miles C. Barr, Cambridge, MA (US); Rachel M. Howden, Cambridge, MA (US); Karen K. Gleason, Cambridge, MA (US); Vladimir Bulovic, Lexington, MA (US)

(73) Assignee: Massachusetts Institute of Technology, Cambridge, MA (US)

(21) Appl. No.: 14/378,544

(22) PCT Filed: Feb. 13, 2013
(86) PCT No.: PCT/US13/25923

§ 371 Date: Aug. 13, 2014

Related U.S. Application Data
(60) Provisional application No. 61/598,323, filed on Feb. 13, 2012.

(51) Int. Cl. H01L 51/00; H01L 51/44

(52) U.S. Cl. CPC H01L 51/0037; H01L 51/442; H01L 51/441; H01L 51/0097; H01L 51/0021; H01L 51/0056; H01L 51/0046
USPC 136/256; 136/252; 438/93

(57) ABSTRACT

The present invention generally relates to electrodes formed by oxidative chemical vapor deposition and related methods and devices.

### RELATED APPLICATIONS

The present application claims priority to U.S. Provisional Application, Ser. No. 61/598,323, filed Feb. 13, 2012, entitled “ELECTRODES FORMED BY OXIDATIVE CHEMICAL VAPOR DEPOSITION AND RELATED METHODS AND DEVICES,” by Barr et al., herein incorporated by reference.

### FIELD OF THE INVENTION

The present invention generally relates to electrodes formed by oxidative chemical vapor deposition and related methods and devices.

### BACKGROUND OF THE INVENTION

Organic photovoltaics (OPVs) have gained significant momentum as a possible low-cost energy source and have recently reached record efficiencies of nearly 10%, suggesting near-term commercial potential. One particularly promising direction is deployment on the surface of everyday items, such as wall coverings, product packaging, documents, and apparel, enabled by mechanically flexible device layers, low-temperature manufacturing requirements, and low toxicity. For example, there has been significant recent interest in integrating electronics on paper substrates. However, for these applications, the OPV must be compatible with opaque substrates.

In the conventional orientation, an OPV is illuminated through a transparent hole-collecting anode deposited on a substrate, typically indium-tin oxide (ITO), and electrons are collected by a low work function metal cathode top contact. This structure necessitates that the substrate be transparent (e.g. glass or optically clear plastics). Alternative top-illuminated OPV architectures that are compatible with opaque substrates require deposition and patterning of a transparent electrode on top of the complete organic device stack. Such devices have previously been demonstrated with sputtered ITO top anodes with a MoO₃ anode buffer layer. Transparent ITO top cathodes have also been demonstrated on top of a bathocuproine (BCP) exciton blocking layer in opaque and visible-light transparent small molecule OPVs on glass substrates. However, in these configurations, the ITO transparent electrode must be sputtered on top of the full device which can damage underlying organic layers, and is prone to cracking on highly flexible substrates. As an alternative to sputtered metal-oxide transparent top electrodes, ultrathin metal films deposited by vacuum thermal evaporation, have also been demonstrated as the top transparent cathode in top-illuminated, small molecule organic OPVs.

### SUMMARY OF THE INVENTION

In some embodiments a photovoltaic cell is provided comprising a first electrode; a second electrode; a photoactive material positioned between the first electrode and the second electrode; and a substrate, wherein the second electrode is positioned between the photoactive material and the substrate, wherein the first electrode is formed by or formable by oxidative chemical vapor deposition.

In some embodiments, a photovoltaic cell is provided comprising a first electrode; a second electrode; a photoactive material positioned between the first electrode and the second electrode; and a substrate, wherein the second electrode is positioned between the photoactive material and the substrate, wherein the first electrode is formed by or formable by polymerization of vapor phase precursors.

In some embodiments, a method of forming a photovoltaic cell is provided comprising providing a substrate; depositing a second electrode on the substrate; optionally depositing a second electrode buffer material on the second electrode; depositing a photoactive material on the second electrode or the optionally deposited second electrode buffer material; optionally depositing a first electrode buffer material on the photoactive material; and depositing, via oxidative chemical vapor deposition, a first electrode on the photoactive material or the optionally deposited first electrode buffer material.

### BRIEF DESCRIPTION OF THE DRAWINGS

FIG. 1 shows schematics of device structures and materials according to some embodiments: (a) chemical structures of DBP, C₆₀, BCP, and CVD PEDOT polymerized and doped with FeCl₃; (b) conventional orientation PV device with transparent ITO anode (device is illuminated from the substrate side); and (c) top-illuminated orientation PV device with transparent CVD PEDOT anode (device is illuminated from the device side).

FIG. 2 shows (a) representative J-V performance curves measured under 1.1 sun illumination; and (b) external quantum efficiency spectra, for a conventional device with ITO anode (dotted) and top-illuminated devices with CVD PEDOT anode, with (solid) and without (dashed) MoO₃ as a buffer layer.

FIG. 3 shows UV-visible absorbance spectra for (a) glass/DBP (25 nm)/MoO₃ (0 nm (i) and 20 nm (ii)) and (b) glass/C₆₀ (40 nm)/MoO₃ (0 nm (i) and 20 nm (ii)), according to some embodiments.

FIG. 4 shows performance parameters for top-illuminated cells (solid symbols) with different MoO₃ buffer layer thicknesses, measured under 1.1 sun illumination: (a) short-circuit current density (diamonds), (b) open-circuit voltage (circles), (c) fill factor (triangles), and (d) power conversion efficiency (squares), according to some embodiments.

FIG. 5 shows (a) representative J-V curves for top-illuminated OPVs fabricated on the top side of some common opaque substrates under 1.1 sun illumination, including photo paper, magazine print, a U.S. first-class stamp, plastic food packaging, and glass for reference, according to some embodiments; and (b) photographs of completed 10 device arrays according to some embodiments.

FIG. 6 shows a representative rinsing process after oCVD, according to some embodiments.

FIG. 7 shows representative X-ray photoelectron spectroscopy survey scans for rinsed oCVD films, according to one set of embodiments.

FIG. 8 shows (a) UV-Vis spectra for rinsed oCVD films; and (b) transmittance at 560 nm versus sheet resistance trade-off for rinsed oCVD films (methanol (i), 2 M HCl (ii), 2 M HBr (iii), 2 M H₂SO₄ (iv)), according to some embodiments.

FIG. 9 shows stability of sheet resistance for films after different rinsing conditions at elevated temperatures (a) 30° C. (b) 50° C. (c) 80° C., according to some embodiments.

FIG. 10 shows (a) Raman spectra of oCVD films after different rinsing conditions: (i) MeOH, (ii) 1 M HCl, (iii) 1 M HBr, and (iv) 1 M H2SO4; (b) photographs of patterned oCVD films (i) unrinsed (ii) rinsed in 0.5 M HCl and (iii) rinsed in 0.5 M HCl, according to some embodiments.

Other aspects, embodiments and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### DETAILED DESCRIPTION

The present invention generally relates to electrodes formed by oxidative chemical vapor deposition and related methods and devices. In some embodiments, the device is a photovoltaic cell. In some embodiments, the photovoltaic cell is an inverted photovoltaic cell, wherein the cell is illuminated through an electrode not associated with a substrate (e.g., an opaque substrate).

Photovoltaic cells will be known to those of ordinary skill in the art. Generally, a photovoltaic cell comprises at least a substrate, a first electrode, a second electrode associated with the substrate, a photoactive material disposed between the first electrode and the second electrode, and optionally, a first electrode buffer material disposed between the first electrode and the photoactive material and/or a second electrode material layer disposed between the second electrode and the photoactive material. The device may be exposed to electromagnetic radiation through the substrate (e.g., convention photovoltaic cell) or through the first electrode which is not associated with the substrate (e.g., inverted photovoltaic cell). Photovoltaic cells, components, orientations, and methods of use will be known to those of ordinary skill in the art.

It should be understood, that while many of the embodiments described herein are discussed in relation to photovoltaic cells, this is by no means limiting, and other devices (e.g., electromagnetic radiation absorbing and/or emitting devices) may be employed.

In some embodiments, photovoltaic cell or methods for forming photovoltaic cells are provided, wherein the photovoltaic cell comprises a first electrode; a second electrode; a photoactive material positioned between the first electrode and the second electrode; and a substrate, wherein the second electrode is positioned between the photoactive material and the substrate. In some embodiments, the first electrode is transparent or substantially transparent. A photovoltaic cell comprising a transparent or substantially transparent first electrode allows for operation of the device by exposing the device to electromagnetic radiation via the first electrode (e.g., not associated with the substrate) as opposed to through the substrate. This allows for use of opaque or substantially opaque substrates. Accordingly, in some embodiments, the substrate is opaque or substantially opaque. In some embodiment, the substrate is flexible. Substrates are described in more detail herein.

In some embodiments, the first electrode comprises a conductive polymer. In some embodiments, the first electrode is formed via oxidative chemical vapor deposition (oCVD). In some embodiments, the first electrode is formed by polymerization of vapor phase precursors. The conductive polymer formed by oCVD may be transparent or substantially transparent.

In some embodiments, the transmittance of the first electrode in the ultraviolet-visible range is greater than or equal to about 40%, or about 50%, or about 60%, or about 70%, or about 80%, or about 90%, or about 95%, or about 97, or about 99%. In some instances, the transmittance of the first electrode in the ultraviolet-visible range (e.g. at 560 nm) is between about 40% and about 100%, or between about 50% and about 100%, or between about 60% and about 100%, or between about 70% and about 100%, or between about 80% and about 100%, or between about 90% and about 100%, or between about 95% and about 100%, or between about 97% and about 100%, or between about 99% and about 100%. In some embodiments, the transmittance is determine at a wavelength between about 200 nm and about 2,000 nm, or between about 200 nm and about 1,500 nm, or between about 200 nm and about 1,000 nm, or between about 200 nm and about 800 nm, or between about 300 nm and about 800 nm, or between about 400 nm and about 800 nm, or between about 500 nm and about 800 nm, or between about 500 nm and about 600 nm. In some embodiments, the transmittance is determined at a wavelength of 550 nm. In some embodiments, the transmittance is determined at a wavelength of 560 nm. Those of ordinary skill in the art will be aware of methods and systems for determining the transmittance of the first electrode. For example, the transmittance of the first electrode may be determined by using a UV-Vis spectrometer to scan a wavelength range of 200 to 2,000 nm and measure the transmittance at a specific wavelength within that range.

In some embodiments the conductivity of the first electrode is greater than or equal to about 50 S/cm, or about 100 S/cm, or about 200 S/cm, or about 400 S/cm, or about 600 S/cm, or about 800 S/cm, or about 1,000 S/cm, or about 1,200 S/cm, or about 1,400 S/cm, or about 1,600 S/cm, or about 1,800 S/cm. In some instance, the conductivity of the first electrode is between about 50 S/cm to about 2,000 S/cm, or between about 200 to 2,000 S/cm, or between about 400 to about 2,000 S/cm, or between about 600 to 2,000 S/cm, or between about 800 to 2,000 S/cm, or between about 1,000 to 2,000 S/cm, or between about 50 S/cm to about 1,000 S/cm, or between about 200 S/cm to about 1,000 S/cm, or about 400 S/cm to about 1,000 S/cm. Those of ordinary skill in the art will be aware of methods and systems for determining the sheet resistance of the first electrode. For example, the conductivity may be determined by measuring the sheet resistance with a four point probe device and measuring the film thickness by any suitable method.

In some embodiments, the ratio of the optical conductivity to the direct current conductivity (σₒₚ/σ_{dc}) of the first electrode is greater than or equal to about 2, or about 4, or about 6, or about 8, or about 10, or about 12, or about 15, or about 20, or about 25, or about 30, or about 35. In some instances, the ratio of the optical conductivity to the direct current conductivity (σₒₚ/σ_{dc}) of the first electrode is between about 2 and about 40, or between about 4 and about 40, or between about 6 and about 40, or between about 8 and about 40, or between about 12 and about 40, or between about 15 and about 40, or between about 20 and about 40, or between about 25 and about 40. Those of ordinary skill in the art will be aware of methods and systems for determining the ratio of the optical conductivity to the direct current conductivity of the first electrode. For example, the optical conductivity and the direct current conductivity may be determined by fitting experimental data of percent transmittance versus sheet resistance to an equation relating transmittance and sheet resistance as provided herein.

In some embodiments, the sheet resistance (Rₛₕ) of the first electrode is greater than or equal to about 40 ohms, or about 100 ohms, or about 200 ohms, or about 500 ohms, or about 800 ohms, or about 1,000 ohms, or about 1,500 ohms, or about 1,000 ohms, or about 5,000 ohms, or about 10,000 ohms, or about 15,000 ohms. In some instance, the sheet resistance of the first electrode is between about 40 ohms to about 100 ohms, or between about 40 to 200 ohms, or between about 40 to about 500 ohms, or between about 40 to 800 ohms, or between about 40 to 1,000 ohms, or between about 40 to 1,500 ohms, or between about 40 ohms to about 5,000 ohms, or between about 40 ohms to about 10,000 ohms, or about 40 ohms to about 15,000 ohms. Those of ordinary skill in the art will be aware of methods and systems for determining the sheet resistance of the first electrode. For example, the sheet resistance may be determined using a four point probe device.

oCVD techniques with be known to those of ordinary skill in the art and are described in the literature, for example, see, M. E. Alf et al., Adv. Mater. 22, 1993 (2010); and S. H. Baxamusa, S. G. Im, K. K. Gleason, Phys. Chem. Chem. Phys. 11, 5227 (2009), each herein incorporated by reference. As will be known to those of ordinary skill in the art, oCVD, is a solvent-free, vacuum-based technique, in which conjugated polymer films are formed directly on the substrate by oxidative polymerization of vapor-phase monomer and oxidant precursors at low temperature (25-150° C.) and under moderate vacuum (˜0.1 Torr). Well-defined polymer patterns can be “vapor-printed” on the material of choice when this process is combined with in situ shadow masking. Thus, oCVD offers an attractive solvent-free route to transparent polymer top electrodes, while maintaining the benefits of vacuum processing, including parallel and sequential deposition, well-defined thickness control and uniformity, and inline compatibility with standard vacuum process (e.g. thermal evaporation). Moreover, oCVD is conformal over nonplanar substrates, enabling compatibility with substrates such as paper and textiles. In contrast, vacuum thermal evaporation is generally subject to line-of-sight deposition, while conformal deposition of liquid-phase systems is complicated by surface tension effects around micro- and nano-scale features.

In some embodiments, oCVD methods comprise providing a vapor-phase monomer species and a vapor-phase oxidizing agent to produce a vapor comprising a conductive polymer precursor and contacting the vapor with the surface to form the electrode comprising a conductive polymer on the surface. In some embodiments, due to presence of excess oxidizing agent, a doped or oxidized polymer species may be generated in vapor phase and may form on the surface. In an illustrative embodiment, the method may involve oxidative polymerization of thiophene to a doped form of polythiophene, wherein the polythiophene is in oxidized form and contains polarons and bipolarons. As described herein, following formation of the first electrode, the first electrode may be further treated, exposed, or associated with a secondary material which may alter the properties of the first electrode. For example, post-treatment of the first electrode with an acid solution such as sulfuric acid may improve properties (e.g., conductivity, transmittance, crystallinity, roughness, ratio of the optical conductivity to the direct current conductivity, stability, sheet resistance) of the first electrode. In some embodiments, the first electrode may be treated a first type of secondary material (e.g., an acidic solution) and a second type of secondary material (e.g., alcohol such as methanol).

Accordingly, in some embodiments, the first electrode comprises a conductive polymer. In some embodiments, the conductive polymer is a conjugated polymer. The conjugated polymer may be polyacetylene, polyarylene, polyarylene vinylene, or polyarylene ethynylene, any of which are optionally substituted. In some cases, the conjugated polymer is polyphenylene, polythiophene, polypyrrole, polyaniline, or polyacetylene, any of which are optionally substituted. In some embodiments, the conjugated polymer is a copolymer. In one set of embodiments, the polymer is an optionally substituted polythiophene. In a particular embodiment, the conjugated polymer is an unsubstituted polythiophene. In some embodiments, the conjugated polymer is a copolymer of thiophene.

Poly(thiophenes) will be known to those of ordinary skill in the art and generally contain the repeating unit:

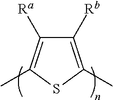

wherein R^{a} and R^{b} can be the same or different and each can independently be hydrogen, alkyl, heteroalkyl aryl, heteroaryl, arylalkyl, arylheteroalkyl, heteroarylalkyl, each optionally substituted, or R^{a} and R^{b} can be joined to form an optionally substituted ring (e.g., a saturated or unsaturated ring); and n can be any integer between 2 and 100,000,000. In some embodiments, R^{a} and R^{b} are hydrogen.

Those of ordinary skill in the art will be able to select the appropriate monomer species for use in a particular application to formed the conductive polymer. In some cases, the monomer species is a compound comprising an aryl or heteroaryl group, any of which is optionally substituted. The monomer species may be, for example, an optionally substituted heteroaryl group such as an optionally substituted thiophene. Examples of aryl or heteroaryl groups include, but are not limited to phenyl, naphthyl, tetrahydronaphthyl, indanyl, indenyl, fluorenyl, pyridyl, pyrazinyl, pyrimidinyl, pyrrolyl, pyrazolyl, imidazolyl, thiazolyl, oxazolyl, isooxazolyl, thiadiazolyl, oxadiazolyl, thiophenyl, furanyl, quinolinyl, isoquinolinyl, and the like, any of which is optionally substituted. In some embodiments, the monomer species is 3,4-ethylenedioxythiophene

Examples of oxidizing agents for use in the oCVD processes include, but are not limited to, CuCl₂, FeCl₃, FeBr₃, I₂, POBr₃, GeCl₄, SbI₃, Br₂, SbF₅, SbCl₅, TiCl₄, POCl₃, SO₂Cl₂, CrO₂Cl₂, S₂Cl, O(CH₃)₃SbCl₆, VCl₄, VOCl₃, BF₃, (CH₃(CH₂)₃)₂O.BF₃, (C₂H₅)₃O(BF₄), or BF₃.O(C₂H₅)₂. In one embodiment, the oxidizing agent is FeCl₃.

In some embodiments, the first electrode may undergo one or more post-treatment steps following the oCVD process. Post-treatment after oCVD may alter the final electrical and/or physical properties of the first electrode. In some instances, the post-treatment may comprise exposing the first electrode to a secondary material. In some cases, the post-treatment may comprise a chemical rinsing step, such as an acid rinsing step. The chemical rinsing step may remove oxidants, perform dopant exchange, change film morphology (e.g., increase crystallinity, decrease roughness), tune the work function, and/or reduce sheet resistance of the first electrode.

In some embodiments, the rinsing step may comprise exposing (e.g., rinsing) the first electrode (e.g., via immersion) to at least one acidic solution. In some instances, the first electrode may be exposed to a single acidic solution and in other instances, the first electrode may be exposed to more than one acidic solution. In certain cases, the first electrode may be exposed to at least one acidic solution and at least one non-acidic solution (e.g. methanol). In embodiments, in which more than one rinse solution is used (e.g., acidic solution followed by methanol), the first electrode may be dried between exposures. In other cases, the first electrode may not be dried between exposures.

Those of ordinary skill in the art will be able to determine suitable parameters (e.g., concentration, temperature, time) for exposing the first electrode to an acid or other secondary material. In general, the rinse time, rinse solution temperature, and solution concentration may be selected as desired for a given application. In some embodiments, the concentration of the acidic solution is between about 0.01 M and about 10 M, or between about 0.01 M and about 8M, or between about 0.01 M and about 5M, or between about 0.1 M and about 5M, or between about 0.5 M and about 5M, or between about 1 M and about 5M, or between about 1 M and about 3 M, or between about 1 M and about 2 M. In some embodiments, the temperature that the exposure is conducted at and/or the temperature of the rinse solution is between about 10° C. and about 150° C., or between about 20° C. and about 150° C., or between about 20° C. and about 140° C., or between about 20° C. and about 100° C., or between about 20° C. and about 80° C., or between about 20° C. and about 60° C., or between about 20° C. and about 40° C., or between about 20° C. and about 30° C. In some embodiments, the first electrode is exposed to the acid solution for a period of time between about 0.1 seconds and 100,000 seconds, or between about 0.1 seconds and about 60,000 seconds, or between about 1 seconds and about 60,000 seconds, or between about 10 seconds and about 60,000 seconds, or between about 60 seconds and about 600,000 seconds, or between about 60 seconds and about 60,000 seconds, or between about 60 seconds and about 6,000 seconds, or between about 60 seconds and about 1,000 seconds, or between about 60 seconds and about 600 seconds, or between about 100 seconds and about 600 seconds, or between about 300 seconds and about 600 seconds.

In some cases, the first electrode may be rinsed at ambient conditions (e.g., ambient temperature and pressure) with an acidic solution that has a molarity between about 0.001 M and about 5.0 M. In certain cases, the first electrode may be rinsed at temperature between about 20° C. and about 140° C. with an acidic solution that has a molarity between about 0.1 M and about 5 M for between about 1 second to about 6,000 seconds.

Those of ordinary skill in the art will be able to select the appropriate acid solution for a particular application for exposing the first electrode after the oCVD process. For instance, the appropriate acid solution may comprise an acid known to undergo remove oxidants and/or dopant exchange with films. In some cases, the acidic solution may comprise an inorganic acid (e.g., hydrochloric acid, hydrobromic acid, sulfuric acid, hydroiodic, nitric acid, hypochlorous acid, chloric acid, perchloric acid, phosphoric acid, nitrous acid). In other cases, the acidic solution may comprise an organic acid (e.g., camphor-10-sulfonic acid, acetic acid, formic acid). In some cases, the acid is hydrobromic acid, hydrochloric acid, or sulfuric acid. In certain cases, the acid is camphor-10-sulfonic acid. In some instances, the acid is a strong protic acid (e.g., hydrobromic acid, hydrochloric acid, perchloric acid, sulfuric acid).

In some embodiments, the rinsing step may comprise exposing (e.g., rinsing) the first electrode (e.g., via immersion) to at least one alcohol (e.g., methanol). In some instances, the first electrode may be exposed to a single alcohol and in other instances, the first electrode may be exposed to more than one alcohol. In certain embodiments, the conditions for exposing the alcohol to the first electrode (e.g., rinse temperature, rinse time, alcohol concentration, etc.) may be within the ranges provided for exposure to an acidic solution. In some embodiments, the first electrode is exposed to an acid, followed by exposure to an alcohol.

In some embodiments, following exposing the first electrode to a secondary material (e.g., acid, alcohol), the conductivity, ratio of the optical conductivity to the direct current conductivity (σₒₚ/σ_{ac}), sheet resistance, and/or transmittance of the first electrode may improve as compared to the first electrode prior to exposure.

In some embodiments, the increase in conductivity of the first electrode following exposure to a secondary material (e.g., acid) is greater than or equal to about 10%, or about 30%, or about 50%, or about 70%, or about 90%, or about 110%, or about 130%, or about 150%, or about 170% as compared to the conductivity of the first electrode prior to exposure, measured under substantially similar conditions. In some instances, the increase in conductivity of the first electrode following exposure to a secondary material (e.g., acid) is between about 10% and about 200%, or between about 10% and about 170%, or between about 10% and about 150%, or between about 30% and about 150%, or between about 50% and about 150%, or between about 70% and about 150%, or between about 90% and about 150%, or between about 110% and about 150%.

In certain embodiments, the chemical rinse step may increase the ratio of the optical conductivity to the direct current conductivity (σₒₚ/σ_{dc}), and accordingly the transmittance, of the first electrode for a given sheet resistance. In some instances, the increase in the ratio of the optical conductivity to the direct current conductivity of the first electrode following exposure to a secondary material (e.g., acid) is greater than or equal to about 50%, or about 75%, or about 100%, or about 125%, or about 150%, or about 175%, or about 200%, or about 250% as compared to the conductivity of the first electrode prior to exposure, measured under substantially similar conditions. In some instances, the increase in the ratio of the optical conductivity to the direct current conductivity of the first electrode following exposure to a secondary material (e.g., acid) is between about 50% to about 300%, or between about 50% to about 250%, or between about 50% to about 200%, or between about 100% to about 300%, or between about 100% to about 250%, or between about 100% to about 200%. In some cases, rinsing the first electrode with hydrobromic acid may increase the ratio of the optical conductivity to the direct current conductivity from 4 to 12.

In some embodiments, the increase in transmittance at a given wavelength of the first electrode following exposure to a secondary material (e.g., acid) is greater than or equal to about 10%, or about 30%, or about 50%, or about 70%, or about 90%, or about 110%, or about 130%, or about 150%, or about 170% as compared to the transmittance of the first electrode prior to exposure, measured under substantially similar conditions.

In certain embodiments, the sheet resistance of the first electrode may decrease following exposure to a secondary material. In some instances, the decrease in sheet resistance following exposure to a secondary material (e.g., acid) is greater than or equal to about 50%, or about 75%, or about 100%, or about 125%, or about 150%, or about 175%, or about 200%, or about 250% as compared to the sheet resistance of the first electrode prior to exposure, measured under substantially similar conditions. In some instances, the decrease in sheet resistance of the first electrode following exposure to a secondary material (e.g., acid) is between about 50% to about 300%, or between about 50% to about 250%, or between about 50% to about 200%, or between about 100% to about 300%, or between about 100% to about 250%, or between about 100% to about 200%.

In some embodiments, a property of the first electrode may be directly proportional to another property of the first electrode, such that changes in one property may result in changes to another property. For instance, in some embodiments, the transmittance (T) for a given wavelength (e.g., 560 nm), sheet resistance (Rₛₕ), optical conductivity (σₒₚ), and direct current conductivity (σ_{dc}) of the first electrode may be related by the following equation, where Z₀ is the impedance of free space (i.e., 377 ohms).

$$T = {( 1 + \frac{{Z}_{0}}{2 {R}_{sh}} \frac{{σ}_{op}}{{σ}_{dc}} )}^{- 2}$$

In one example, decreasing sheet resistance of the first electrode may increase the transmittance of the first electrode.

Conductive polymer electrodes based on poly(3,4-ethylenedioxythiophene) (PEDOT) are an attractive alternative transparent electrode due to their potential low cost, ease of processing, and/or mechanical robustness on highly flexible substrates, such as plastic, textiles, and paper. However, solution deposited PEDOT (e.g., doped with poly(styrenesulfonate) (PEDOT:PSS)) configurations generally require that the underlying device layers do not dissolve or intermix during the solvent deposition process, restricting applicability in many multilayered and tandem device architectures, and limiting demonstrations to single-junction P3HT:PCBM cells. In some embodiments, the first electrode comprises poly(3,4-ethylenedioxythiophene) (PEDOT).

In some embodiments, a photovoltaic cell comprises a transparent anode; a cathode; a photoactive material positioned between the transparent anode and the cathode; and an substrate (e.g., an opaque substrate), wherein the cathode is positioned between the photoactive material and the substrate, wherein the transparent anode is formed via oxidative chemical vapor deposition. In some embodiments, a photovoltaic cell comprises a transparent anode comprising a conductive polymer; a cathode; a metal oxide (e.g., an anode buffer material); a photoactive material; a substrate (e.g., an opaque substrated), wherein the metal oxide is positioned between the transparent anode and the photoactive material, wherein the photoactive material is positioned between the metal oxide and the cathode, and wherein the cathode is positioned between the photoactive material and the substrate.

Methods described herein may be useful in the fabrication of devices, including photovoltaic devices (e.g. solar, cells), light-emitting diodes, or any device having a photoactive material, a first electrode, and a second electrode. Photovoltaic cells will be known to those of ordinary skill in the art. In some embodiments, a method of forming a photovoltaic cell comprises providing a substrate; depositing a second electrode on the substrate; optionally depositing a second electrode buffer material on the second electrode; depositing a photoactive material on the second electrode or the optionally deposited second electrode buffer material; optionally depositing a first electrode buffer material on the photoactive material; and depositing, via oxidative chemical vapor deposition, a first electrode on the photoactive material or on the optionally deposited first electrode buffer material. In some embodiments, the first electrode is an anode and the second electrode is a cathode. In other embodiments, the second electrode is an anode and the first electrode is a cathode. In some cases, the device is exposed to electromagnetic radiation via the first electrode.

In some embodiments, a method of forming a photovoltaic cell comprises providing an substrate (e.g., an opaque substrate); depositing a cathode on the substrate; optionally depositing a cathode buffer material on the cathode depositing a photoactive material on the cathode or the optionally deposited cathode buffer material; optionally depositing an anode buffer material on the photoactive material; and depositing via oxidative chemical vapor deposition an anode on the photoactive material or the optionally deposited anode buffer material.

In some embodiments, the efficiency of the photovoltaic cell is greater than about 2%, or about 2.1%, or about 2.2%, or about 2.3%, or about 2.4%, or about 2.5%, or about 2.6%, or about 2.7%, or about 2.8%, or about 2.9%, or about 3.0%. In some embodiments, the efficiency of the photovoltaic cell is between about 2% and about 10%, or between about 2% and about 9%, or between about 2% and about 7%, or between about 2% and about 6%, or between about 2% and about 5%, or between about 2% and about 4%, or between about 2% and about 3%, or between about 2% and about 2.5%.

Each of the components and/or layers of the device (e.g., photovoltaic cell) may any suitable thickness. In some embodiments, each material may be of substantially uniform thickness (e.g., wherein the thickness of the material does not vary more than 10%, or more than 5%, or more than 1% over the surface of the article). The thickness of each material may be between about 1 nm and about 1000 nm, or between about 1 nm and about 500 nm, or between about 1 nm and about 300 nm, or between about 1 nm and about 200 nm, or between about 1 nm and about 100 nm, or between about 1 nm and about 50 nm, or between about 10 nm and about 100 nm, or between about 10 nm and about 50 nm, or between about 10 nm and about 40 nm. In some embodiments, the thickness of the each material may be about, or greater than or less than, about 5 nm, about 10 nm, about 15 nm, about 20 nm, about 25 nm, about 30 nm, about 40 nm, about 50 nm, about 60 nm, about 70 nm, about 75 nm, about 80 nm, about 90 nm, about 100 nm, about 150 nm, or about 200 nm.

Those of ordinary skill in the art will be able to select suitable photoactive materials for use in the methods and devices described herein. In some cases, a photoactive material comprises an electron-donating material and an electron-accepting material. Those of ordinary skill in the art will be able to select suitable electron-donating materials (e.g., p-type materials) and electron-acceptor materials (e.g., n-type materials) for use in the embodiments described herein.

The term “p-type material” is given its ordinary meaning in the art and refers to a material that has more positive carriers (holes) than negative carriers (electrons). In some embodiments, the electron-donating material comprises a phthalocyanine, a merocyanine dye, or an optionally substituted conjugated polymer based on polythiophene. Non-limiting examples of electron-donating materials are tetraphenyldibenzoperiflanthene (DBP), copper phthalocyanine, chloroaluminum phthalocyanine, and tin phthalocyanine. Those of ordinary skill in the art will be able to select suitable p-type materials for use in the devices and methods described herein.

The term “n-type material” is given its ordinary meaning in the art and refers to a material that has more negative carriers (electrons) than positive carriers (holes). Non-limiting examples of n-type materials include aromatic hydrocarbons including fullerenes, inorganic nanoparticles, carbon nanorods, inorganic nanorods, polymers containing moieties capable of accepting electrons or forming stable anions, or combinations thereof. In some embodiments, the n-type material is a fullerene, optionally substituted. As used herein, the term “fullerene” is given its ordinary meaning in the art and refers to a substantially spherical molecule generally comprising a fused network of five-membered and/or six-membered aromatic rings. For example, C₆₀ is a fullerene which mimics the shape of a soccer ball. The term fullerene may also include molecules having a shape that is related to a spherical shape, such as an ellipsoid. It should be understood that the fullerene may comprise rings other than six-membered rings. In some embodiments, the fullerene may comprise seven-membered rings, or larger. Fullerenes may include C₃₆, C₅₀, C₆₀, C₆₁, C₇₀, C₇₆, C₈₄, and the like. Fullerenes may also comprise individual atoms, ions, and/or nanoparticles in the inner cavity of the fullerene. A non-limiting example of a substituted fullerene which may be used as the n-type material is phenyl-C⁶¹-butyric acid methyl ester. Non-limiting examples of n-type materials are C₆₀,3,4,9,10-perylene tetracarboxylic bisbenzimidazole, TiO₂, and ZnO. Those of ordinary skill in the art will be able to select suitable n-type materials for use in the devices and methods described herein.

In one set of embodiments, the electron-donating material comprises DBP and the electron-accepting material comprises C₆₀.

The substrate can be any material capable of supporting the device components described herein. That is, the substrate may be any material to which a material and/or component described herein may adhere. The substrate may be selected to have a thermal coefficient of expansion similar to those of the other components of the device to promote adhesion and prevent separation of the device components at various temperatures. Non-limiting examples of substrates include glass, plastics, metals, polymers, paper, fabric and the like. The surface may include those constructed out of more than one material, including coated surfaces (e.g., indium tin oxide-coated glass). Non-limiting examples of surfaces include paper, ceramics, carbon, fabric, nylon, polyester, polyurethane, polyanhydride, polyorthoester, polyacrylonitrile, polyphenazine, latex, teflon, dacron, acrylate polymer, chlorinated rubber, fluoropolymer, polyamide resin, vinyl resin, Gore-Tex™, Marlex™, expanded polytetrafluoroethylene (e-polythiopheneFE), low density polyethylene (LDPE), high density polyethylene (HDPE), polypropylene (PP), and poly(ethylene terephthalate) (PET). The substrate may be opaque, semi-opaque, semi-transparent, or transparent. In some embodiments, the substrate is flexible. In other embodiments, the substrate is rigid.

In some embodiments, a device may comprise a first electrode buffer material positioned between the first electrode and the photoactive material and/or a second electrode buffer material positioned between the second electrode and the photoactive material. The buffer materials may reduce the work function of one or more components. Those of ordinary skill in the art will be aware of suitable anode buffer materials for use in the methods and devices as described herein. Non-limiting examples of buffer materials include metal oxides (e.g., MoO₃, V₂O₅ or WO₃) and bathocuproine (BCP).

In some embodiments, a device comprises a first electrode buffer material disposed between the first electrode and the photoactive material. The first electrode buffer material may function as an electron-block layer and/or a physical buffer layer. The presence of the first electrode buffer layer may prevent the photoactive material from chemically interacting with one or more components during deposition of the first electrode (e.g., via oxidative chemical vapor deposition). In some embodiments, the first electrode buffer material comprises a metal oxide. In some embodiments, the first electrode buffer material comprises MoO₃.

Those of ordinary skill in the art will be aware of suitable materials for use as a second electrode. In some embodiments, the second electrode is a conductive metal. Non-limiting examples of conductive metals include silver, aluminum, calcium, and gold.

Various components of a device, such as the anode, cathode, substrate, anode buffer material, etc., etc. can be fabricated and/or selected by those of ordinary skill in the art from any of a variety of components. Components may be molded, machined, extruded, pressed, isopressed, infiltrated, coated, in green or fired states, or formed by any other suitable technique. Those of ordinary skill in the art are readily aware of techniques for forming components of devices herein. Electromagnetic radiation may be provided to the systems, devices, electrodes, and/or for the methods described herein using any suitable source.

U.S. Provisional Application Ser. No. 61/598,323, filed Feb. 13, 2012, entitled “ELECTRODES FORMED BY OXIDATIVE CHEMICAL VAPOR DEPOSITION AND RELATED METHODS AND DEVICES,” by Barr et al., is incorporated herein by reference.

The following examples are intended to illustrate certain embodiments of the present invention, but are not to be construed as limiting and do not exemplify the full scope of the invention.

### Examples and Embodiments

### Example 1

Abstract: Organic photovoltaic devices typically utilize illumination through a transparent substrate, such as glass or an optically clear plastic. Utilization of opaque substrates, including low cost foils, papers, and textiles, requires architectures that instead allow illumination through the top of the device. In this example, top-illuminated organic photovoltaic devices are demonstrated, employing a dry vapor-printed poly(3,4-ethylenedioxythiophene) (PEDOT) polymer anode deposited by oxidative chemical vapor deposition (oCVD) on top of a small-molecule organic heterojunction based on vacuum-evaporated tetraphenyldibenzoperiflanthene (DBP) and C₆₀ heterojunctions. Application of a molybdenum trioxide (MoO₃) buffer layer prior to oCVD deposition increased the device photocurrent nearly 10 times by preventing oxidation of the underlying photoactive DBP electron donor layer during the oCVD PEDOT deposition, and resulted in power conversion efficiencies of up to 2.8% for the top-illuminated, ITO-free devices, approximately 75% that of the conventional cell architecture with indium-tin oxide (ITO) transparent anode (3.7%). The broad applicability of this architecture was demonstrated by fabricating devices on a variety of opaque surfaces, including common paper products with over 2.0% power conversion efficiency, the highest to date on such fiber-based substrates.

Introduction: In this example top-illuminated OPVs are demonstrated having an oCVD PEDOT transparent anode on top of a small-molecule organic heterojunction based on vacuum-evaporated tetraphenyldibenzoperiflanthene (DBP) and fullerene C₆₀ planar heterojunctions. Application of a molybdenum trioxide (MoO₃) buffer layer prior to oCVD deposition increased the device photocurrent nearly 10 times by preventing oxidation of the underlying photoactive DBP electron donor layer during the oCVD PEDOT deposition, and resulted in power conversion efficiencies of up to 2.8% for these top-illuminated, ITO-free devices, approximately 75% that of the conventional cell architecture with indium-tin oxide (ITO) transparent anode (3.7%).

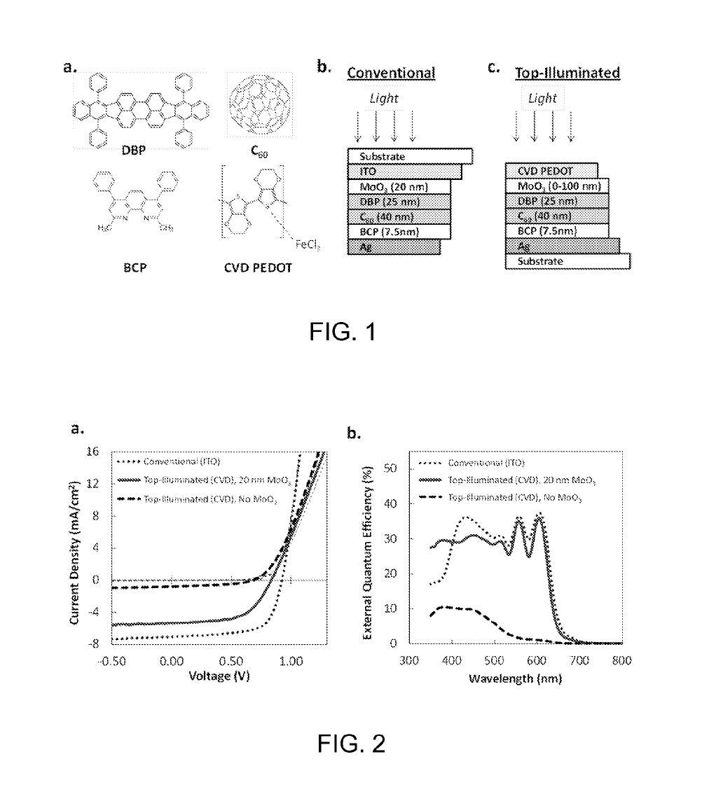

Results and Discussion: For the OPVs in this example, a simple single-junction bilayer structure was used based on thermally evaporated small-molecule organic active layers tetraphenyldibenzoperiflanthene (DBP) as the electron donor and fullerene C₆₀ as the electron acceptor with a bathocuproine (BCP) exciton blocking layer at the cathode interface (FIG. 1a). The conventional orientation device structure on glass/ITO has been discussed previously for these materials, reaching efficiencies of up to 3.6%. A thermally evaporated molybdenum trioxide (MoO₃) layer was optionally inserted at the anode interface, which has previously been demonstrated as an electron-blocking layer and physical buffer layer in polymer and small-molecule organic photovoltaics.

The conventional device structure was first prepared on ITO-coated glass substrates with the thicknesses shown in FIG. 1b (MoO₃ (20 nm)/DBP (25 nm)/C₆₀ (40 nm)/BCP (7.5 nm)/Ag), and used subsequently as a point of comparison. For the top-illuminated device, the same organic active layers and thicknesses were used, while the order of deposition was reversed, starting from the substrate: Ag, BCP, DBP, C₆₀, (MoO₃). For the transparent top electrode, instead of ITO, PEDOT layer was grown by oCVD from the 3,4-ethylenedioxythiophene monomer with FeCl₃ oxidant (FIG. 1c). The thickness of the oCVD PEDOT electrodes used here were 60±10 nm, which was controlled by the time of deposition, and resulted in films with a sheet resistance of ˜200±50 Ω/sq at the conditions used here (see Experimental Section). By using the DBP, C₆₀, and BCP thicknesses from the conventional device and simply reversing the order of the stack, a similar optical environment within the device was expected, since the reflective Ag node was maintained in the same position relative to the DBP/C₆₀ heterojunction interface, thus maintaining a similar positioning of the optical electric field maxima within the respective device layers. However, in the conventional orientation, defect states were likely created in the BCP layer when the metal was deposited on top it, which may aid in providing efficient electron transport through this layer. In the reversed stack, the BCP organic layer was positioned on top of the bottom Ag surface, and thus likely absent of these states which may increase series resistance through the device.

FIG. 2a compares the current density-voltage (J-V) characteristics of the conventional device on ITO with top-illuminated, oCVD PEDOT devices with and without MoO₃ on glass substrates, and a summary of the performance parameters are shown in Table 1. The conventional control device exhibited power conversion efficiency (ηₚ)=3.7±0.3%, open-circuit voltage (V_{OC})=0.93±0.03V, short-circuit current (J_{SC})=6.72±(0.3) mA cm⁻², and fill factor (FF)=0.66±0.04, consistent with previous reports. Inverting the device and replacing the ITO with the oCVD PEDOT top electrode, decreased the J_{sc} to 4.7±1.6 mA cm⁻², V_{OC} to 0.84±0.01 V, and FF to 0.58±0.01, resulting in ηₚ of 2.1±0.6%. The decrease in Jsc may result from small absorptive losses in the less transparent oCVD PEDOT electrode, as observed previously with oCVD PEDOT bottom electrode devices. The FF decreased due to increased series resistance, observable in the J-V curve under forward bias, which may be a result of the more resistive oCVD PEDOT compared to ITO, and possibly deteriorated by the lack of defect states in the BCP layer as discussed above. Removing the MoO₃ between the oCVD PEDOT top electrode and DBP electron donor, decreased the J_{SC} to 0.76±1.6 mA cm⁻², the V_{OC} to 0.68±0.02 V, and FF to 0.44±0.02, resulting in a ηₚ of only 0.21±0.1%.

To understand the origin of the differences in device photocurrent, the external quantum efficiency spectrum was measured for each of these device structures (FIG. 1b). The EQE of the top-illuminated CVD device with MoO₃ was slighty lower than that of the conventional device across the wavelength range, which is consistent with the lower observed J_{SC} due to absorptive losses from the oCVD PEDOT electrode. The characteristic absorption peaks from DBP (570 nm and 610 nm) were evident in the EQE of the conventional device and top-illuminated device with MoO₃; however, did not appear in the top-illuminated device without MoO₃, which shows photocurrent generation below 550 nm, in the region where C₆₀ absorbs, indicating a loss of photocurrent originating from the DBP.

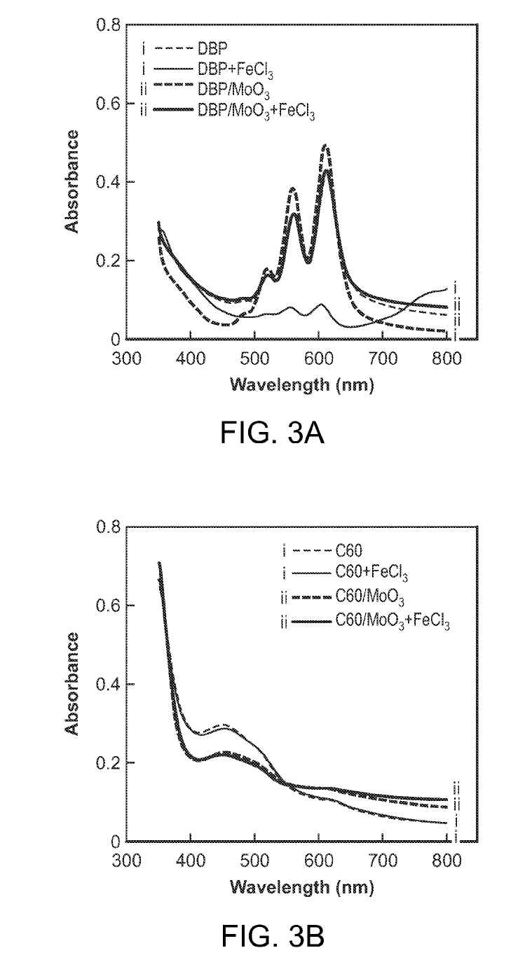

In the devices without MoO₃, the surface of the DBP photoactive layer was exposed to FeCl₃ oxidant precursor during the oCVD process. To better understand this effect, absorption data was collected on blanket films of DBP and C₆₀ both before and after exposure to FeCl₃, in the oCVD chamber, under the same pressure and temperature conditions experienced during PEDOT polymerization. FIG. 3 shows the UV-visible absorbance data for the active layer films before and after FeCl₃ exposure both with and without a MoO₃ buffer layer. Though the C₆₀ absorption remained unchanged (FIG. 3b), the bare DBP absorption peaks decreased significantly upon exposure to FeCl₃ (FIG. 3a). This is consistent with the EQE spectra for the top-illuminated device without MoO₃, which shows photocurrent originating from C₆₀ and suggests that the bare DBP layer may be prone to oxidation by FeCl₃ while the more stable resonant structure of C₆₀ remained unaffected. With the addition of the MoO₃ buffer layer (20 nm) on top of the DBP before exposing to FeCl₃, the absorption peaks of the DBP remained intact, indicating that the thin MoO₃ layer may physically protect the underlying DBP layer from chemically interacting with the FeCl₃ during the oCVD process.

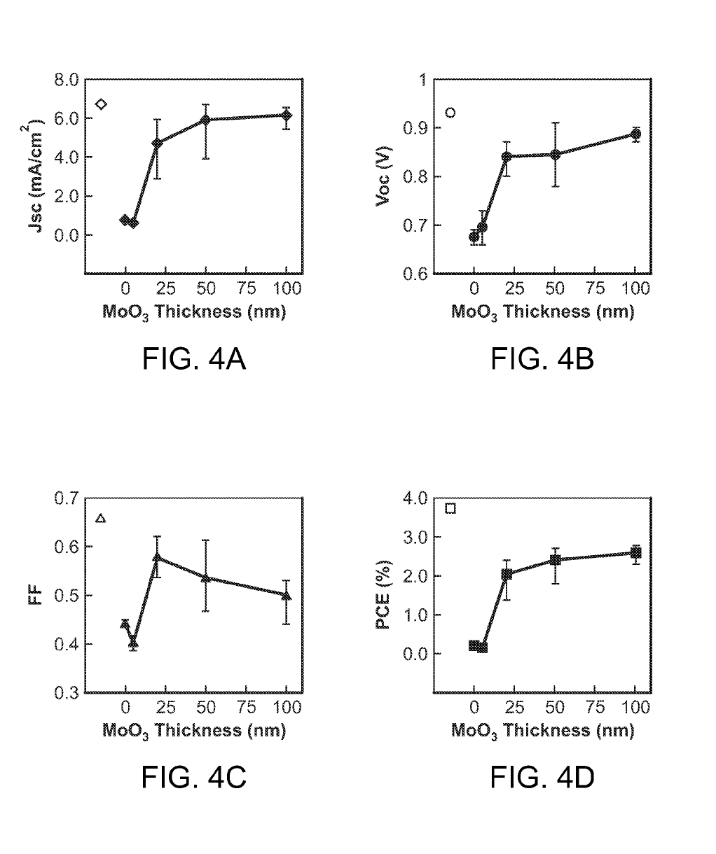

To further understand how this layer affected device performance, top-illuminated devices with oCVD PEDOT electrodes were fabricated using varying thicknesses (0, 2 nm, 20 nm, 50 nm, and 100 nm) of the MoO₃ buffer layer. FIG. 4 shows how the main device characteristics (J_{SC}, V_{OC}, FF, and ηₚ) varied with MoO₃ layer thickness. The ultra-thin MoO₃ layer (2 nm) was found to be too thin to protect the underlying active layers during PEDOT polymerization and these devices showed similarly low Jsc and V_{OC} characteristics as the devices with no MoO₃. Increasing the MoO₃ thickness further from 20 to 100 nm resulted in a plateau in Jsc around 6.0 mA cm⁻² between 20 and 50 nm (FIG. 4a), demonstrating limited additional benefit in protecting the photocurrent generation of the underlying semiconductors. Similarly, the V_{OC} increased and plateaued with increasing MoO₃ thickness (FIG. 4b). The high V_{OC} observed with the MoO₃ layer present is supported by the high work function of MoO₃ (5.7±0.4 eV), compared with the work function of bare CVD PEDOT (5.2±0.1 eV), resulting in increased work function offset between the anode and cathode. It has been also been reported that the MoO₃ work function and band gap both increased with thickness, which can increase Voc by reducing electron leakage current from the donor layer and enhancing hole extraction by increased band banding at the MoO₃/donor interface. The FF gradually decreased with increasing MoO₃ thickness due to increased series resistance through the device (FIG. 4c). The maximum observed ηₚ of 2.8% was achieved for a device with a 100 nm MoO₃ layer (FIG. 4d); however, the optimal MoO₃ thickness may vary and may be lower than 100 nm, where a maximum value for V_{OC}, J_{SC}, and FF was observed. For example, a device having the maximum V_{OC} (0.91 V), J_{SC} (6.7 mA cm⁻²), and FF (0.61) observed with 50 nm MoO₃ (which were not all observed on the same individual device) may give an efficiency of 3.4%.

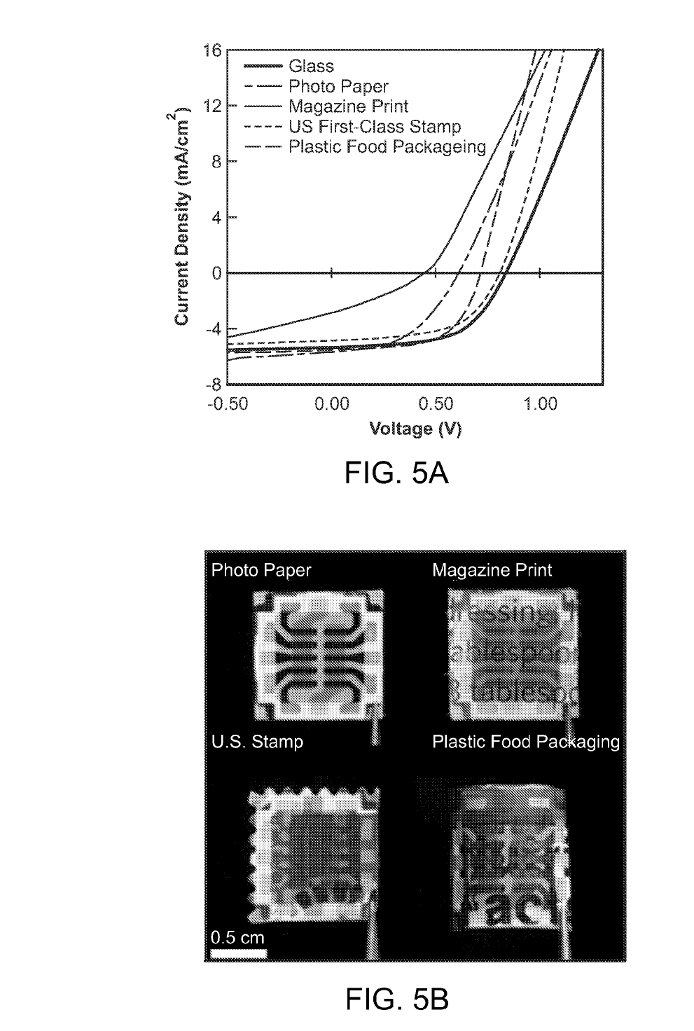

Finally, devices were fabricated and tested on a number of common opaque substrates to demonstrate the wide applicability of this top-illuminated architecture (FIG. 5). Opaque substrates, made from everyday consumer products were selected, included photo paper, magazine print, US first-class stamp, and plastic food packaging. The OPV devices were fabricated and tested in the same way as the cells on glass substrates with a 20 nm MoO₃ buffer layer, and all substrates were used as purchased. The ability to seamlessly transition from fabrication on glass to paper substrates was made possible by avoiding high temperatures and solvent wetting challenges in this all-dry process. Notably, the J-V performance curves (FIG. 5a) showed that inverting the orientation of illumination resulted in photocurrents (J_{SC}) that match closely with that of the cell on the transparent glass substrate, despite the low substrate transparency. This represents a significant improvement over previous demonstrations of bottom-illuminated oCVD PEDOT OPVs on paper substrates, which suffered from low photocurrents due to the low optical transmittance of paper substrates. The low FF for the device on magazine print may be due to low shunt resistance observable in the J-V at zero bias, and may be due to shorting pathways across the thin semiconductor active layers in areas of high surface roughness. A summary of the performance parameters for these devices are listed in Table 2. The efficiency observed on paper substrates (2.0%) has a performance just over half of the conventional ITO device on glass (3.7%) with the same active layer materials, and is the best reported to date for an OPV on a fibrous paper substrate.

Conclusion:

Top-illuminated organic photovoltaics were demonstrated, employing a vapor-printed poly(3,4-ethylenedioxythiophene) (PEDOT) polymer anode deposited by oxidative chemical vapor deposition (oCVD) on top of a small-molecule organic heterojunction based on vacuum-evaporated DBP as the electron donor and fullerene C₆₀ as the electron acceptor. A MoO₃ buffer layer between the oCVD PEDOT top electrode and DBP donor layer is shown to increase the device photocurrent nearly 10 times by preventing oxidation of the underlying photoactive DBP electron donor layer during the oCVD PEDOT deposition, and results in power conversion efficiencies of up to 2.8% for the top-illuminated, ITO-free devices, approximately 75% that of the conventional cell architecture with indium-tin oxide (ITO) transparent anode (3.7%). The broad applicability of this architecture was demonstrated by fabricating devices on a variety of opaque substrates, including common paper products with ˜2.0% power conversion efficiency. By replacing the single-junction bilayer cell used here with tandem and bulk heterojunction structures available today, efficiencies in excess of 5% may be possible on opaque paper-based substrates without any pretreatment or special manufacturing processes. This demonstrates the near-term potential for deploying organic photovoltaics in the form of everyday opaque substrates, thus adding energy harvesting functionality to otherwise passive products, such as wall and window coverings, product packaging, documents, and apparel.

### EXPERIMENTAL

### Substrate Preparation

Pre-cut glass substrates as well as pre-patterned ITO substrates (Thin Film Devices, 20 Ω/sq), for the conventional control devices, were cleaned by subsequent sonication in DI water with detergent, DI water, acetone, and isopropyl alcohol, followed by 30 seconds of O₂ plasma (100 W, Plasma Preen, Inc.). Common opaque substrates (FIG. 5) were cut to size with scissors, but used without any pretreatment or cleaning procedures: photo paper (Office Depot, #394-925); magazine print (food network magazine, inner page); US First Class Stamp (2011 “forever” stamp); and plastic food wrapper (Kellogg's® pop-Tarts™).

### Device Fabrication

The Ag cathode, organic active layers (BCP, C₆₀, and DBP), and MoO₃, were thermally evaporated onto the substrate in sequence through shadow masks at a pressure of ˜1×10⁻⁶ Ton at rates of ˜1.0 Å/s. The C₆₀ (Sigma Aldrich, 99.9%) and DBP (Luminescencev Technology Corp., >99.5%) were each purified once via thermal gradient sublimation before use; the BCP (Luminescence Technology Corp., >99%), MoO₃ (Sigma Aldrich, powder, 99.99%), and Ag (Alfa Aesar, 1-3 mm shot, 99.9999%) were all used as received. PEDOT top electrodes were then deposited directly on top of the partially completed inverted OPVs in a vacuum chamber using the oxidative chemical vapor deposition process (oCVD), which is described in detail elsewhere. Here, the oCVD PEDOT top electrodes were all synthesized during the same deposition at a reactor pressure of ˜le-4 Torr and a substrate temperature of 150° C., via simultaneous exposure to vapors of 3,4-ethylenedioxythiophene (EDOT) monomer (Aldrich 97%) metered at ˜5 sccm and FeCl₃ oxidant (Sigma Aldrich, 99.99%) controllably evaporated from a resistively heated crucible at ˜170° C. for ˜20 min. No post-treatment or solvent rinsing steps were used, as has been described previously. The PEDOT electrodes were patterned in situ during the oCVD process by positioning pre-cut metal shadow masks in intimate contact with the substrate, which were aligned by hand with the pattern of the bottom device layers. The overlap area between the PEDOT top anode and the Ag bottom cathode defined the device area (0.012 cm²), which was measured after testing with an optical microscope. The resulting device structures were either Glass/ITO/MoO₃ (20 nm)/DBP (25 nm)/C₆₀ (40 nm)/BCP (7.5 nm)/Ag (conventional control orientation) and Substrate/Ag/BCP (7.5 nm)/C₆₀ (40 nm)/DBP (XX nm)/Mo03 (20 nm)/oCVD PEDOT (top-illuminated orientation).

### Characterization

Current density-voltage (J-V) characteristics were measured for the completed OPV devices in nitrogen atmosphere using a Keithley 6487 picoammeter. Devices were tested using 110±10 mW cm⁻² illumination provided by a 1 kW xenon arc-lamp (Newport 91191) with an AM 1.5G filter, and the solar simulator intensity was measured with a calibrated silicon photodiode. The external quantum efficiency (EQE) spectra were measured with a Stanford Research Systems SR830 lock-in amplifier, under a focused monochromatic beam of variable wavelength light generated by an Oriel 1 kW xenon arc lamp coupled to an Acton 300i monochromator and chopped at 43 Hz. A Newport 818-UV calibrated silicon photodiode was used to measure the incident monochromatic light intensity. Optical transmittance measurements were made for on the DBP and C₆₀ films before and after FeCl₃ exposure using a Varian Cary 6000UV-Vis-NIR dual-beam spectrophotometer. PEDOT electrode thicknesses were measured on bare glass slides (positioned next to the OPV devices during oCVD deposition) with a Tencor P-16 profilometer and the sheet resistance was measured using a Signatone S-302-4 four-point probe station with a Keithley 4200-SCS semiconductor characterization system.

TABLE 1
Summary of performance parameters under 1.1 sun illumination
for devices on glass substrates (FIG. 2).

| Device | J_{sc} (mA/cm²) | V_{oc} (V) | FF | PCE (%) |
|---|---|---|---|---|
| Conventional | 6.7 ± (0.3) | 0.93 ± (0.03) | 0.66 ± (0.04) | 3.7 ± (0.3) |
| Top- | 4.7 ± (1.6) | 0.84 ± (0.01) | 0.58 ± (0.01) | 2.1 ± (0.6) |
| Illuminated | | | | |
| MoO₃ (20 nm) | | | | |
| Top- | 0.76 ± (0.05) | 0.68 ± (0.02) | 0.44 ± (0.02) | 0.21 ± (0.01) |
| Illuminated | | | | |
| MoO₃ (0 nm) | | | | |

TABLE 2
Summary of performance parameters under 1.1 sun illumination
for devices on common opaque substrates (FIG. 5).

| Device | J_{sc} (mA/cm²) | V_{oc} (V) | FF | PCE (%) |
|---|---|---|---|---|
| Photo Paper | 5.7 | 0.61 | 0.47 | 1.5 |
| Magazine Print | 2.8 | 0.45 | 0.31 | 0.4 |
| U.S. Stamp | 4.8 | 0.81 | 0.57 | 2.0 |
| Plastic Food Package | 5.5 | 0.72 | 0.61 | 2.2 |

In FIG. 1: Schematics of the device structures and materials used in this report: (a) Chemical structures of DBP, C₆₀, BCP, and CVD PEDOT polymerized and doped with FeCl₃. (b) Conventional orientation PV device with transparent ITO anode (device is illuminated from the substrate side). (c) Top-illuminated orientation PV device with transparent CVD PEDOT anode (device is illuminated from the device side).

In FIG. 2: (a) Representative J-V performance curves measured under 1.1 sun illumination and (b) external quantum efficiency spectra, for the conventional device with ITO anode (dotted) and top-illuminated devices with CVD PEDOT anode, with (solid) and without (dashed) MoO₃ as a buffer layer. All devices are on silver-coated glass substrates.

In FIG. 3: UV-visible absorbance spectra for (a) glass/DBP (25 nm)/MoO₃ (0 nm (i) and 20 nm (ii)) and (b) glass/C₆₀ (40 nm)/MoO₃ (0 nm (i) and 20 nm (ii)). Films were measured before (dashed) and after (solid) exposure to FeCl₃ under CVD polymerization conditions.

In FIG. 4: Performance parameters for top-illuminated cells (solid symbols) with different MoO₃ buffer layer thicknesses, measured under 1.1 sun illumination: (a) short-circuit current density (diamonds), (b) open-circuit voltage (circles), (c) fill factor (triangles), and (d) power conversion efficiency (squares). The conventional, bottom-illuminated cell with ITO anode is shown for reference at x=−15 (open symbols). Data points are the average of 3-5 devices measured across each substrate, and error bars represent the maximum and minimum values recorded.

In FIG. 5: (a) Representative J-V curves for top-illuminated OPVs fabricated on the top side of some common opaque substrates under 1.1 sun illumination, including photo paper, magazine print, a U.S. first-class stamp, plastic food packaging, and glass for reference. (b) Photographs of completed 10 device arrays are also shown. All substrates were used as purchased, so the original surface images are visible in the spaces below the completed PV devices (i.e., printed text, Statue of Liberty image, and “Nutritional Facts” text, respectively).

### Example 2

### Abstract

Reduced sheet resistance and longer film stability of oCVD (oxidative chemical vapour deposition) PEDOT films were achieved by including a post-process acid rinse step in the production of the thin films. PEDOT films were rinsed in multiple concentrations of hydrobromic acid, sulfuric acid, and hydrochloric acid to test the effect of acid rinsing on sheet resistance, doping concentration, chemical composition, optical transmittance, and film morphology. XPS, FTIR, Raman spectroscopy, and XRD measurements were taken to determine the morphology and composition of the rinsed films. On average, rinsing films in HCl, HBr, and H₂SO₄ produced conductivity increases of 37%, 135%, and 117%, respectively. The dc to optical conductivity ratio, σ_{dc}/σₒₚ, was increased to 6, 12, and 10, for HCl, HBr, and H₂SO₄ rinsed films respectively as compared to σ_{dc}/σₒₚ=4 for MeOH rinsed films. This example shows evidence of dopant exchange within the films facilitated by the acid rinsing step, as well as increased removal of residual iron chloride oxidant. Exchanging the chlorine with larger dopant molecules facilitated improved film conductivity stability. The XRD measurements in particular show signs of crystallinity in the PEDOT film after acid rinsing in comparison to an amorphous structure observed before this step. In this example, acid rinsing applied as a post-process step alters thin PEDOT films in ways that enhance their ability to function as electrode materials (e.g., in photovoltaic devices).

### Introduction

Acid rinsing was hypothesized to have multiple potential effects on vapor-deposited PEDOT films including fully removing residual reacted and unreacted oxidant from the film, providing a solvating effect allowing dopant ions to be incorporated into the conjugated chain, and lowering film roughness.

### Results and Discussion

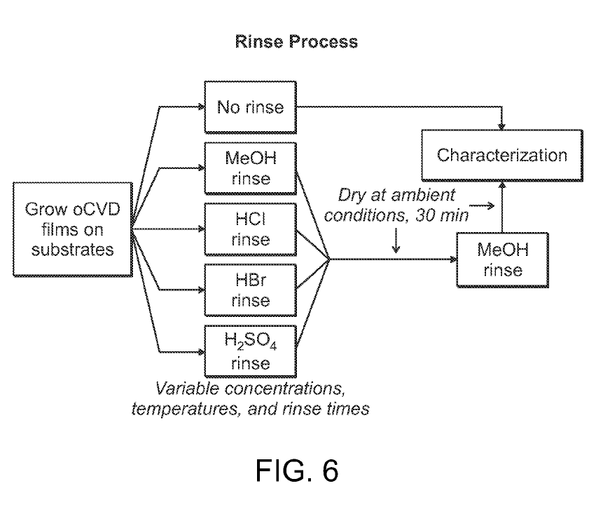

In this example, the effect of acid rinsing on oCVD PEDOT films was determined. In addition to the determination of acid rinse conditions, XPS, FTIR, UV-Vis spectroscopy, Raman spectroscopy, and XRD measurements were taken to characterize the morphology (e.g., crystallinity, roughness, stability) and composition (e.g., presence or absence of dopant) of the rinsed films. In some embodiments, oCVD PEDOT films that underwent an acid rinsing step before rinsing in methanol (MeOH) were demonstrated. The oCVD PEDOT had reduced sheet resistance of the films (e.g., from 40%-135%) and had longer film stability compared to oCVD PEDOT films that only underwent a methanol rinse step. FIG. 6 shows a schematic of the deposition and rinsing process used to prepare samples for characterization. The PEDOT films were formed using an oCVD process and were doped with a combination of Cl⁻ and FeCl₄⁻ anions. After formation, oCVD PEDOT films were rinsed with either an acid or methanol (MeOH), dried, and then rinsed with methanol before characterization. Hydrochloric acid (HCl), hydrobromic acid (HBr), and sulfuric acid (H₂SO₄) were selected for investigation since they had anions that have been previously demonstrated as a dopant with PEDOT films. Alternatively, oCVD PEDOT films were characterized after formation without undergoing a rinsing step (NR).

### Rinse Conditions

The influence of rinsing with each type of acid on conductivity and sheet resistance was determined. The sheet resistance and conductivity of 20 sets of PEDOT films of varying thickness are shown in Table 3. Average conductivity increases of 37%, 135%, and 117% compared to methanol rinsed films were seen for HCl, HBr, and H₂SO₄ rinsed films, respectively. In one embodiment, the maximum observed conductivity was 1620 S cm⁻¹.

TABLE 3
Sheet Resistance and Conductivity Data

| | Sheet Resistance (Ω) | | | | | Thickness (nm) | | | | | Conductivity (S/cm) | | | | |
|---|---|---|---|---|---|---|---|---|---|---|---|---|---|---|---|
| Set # | NR | MeOH | HCl | HBr | H2SO4 | NR | MeOH | HCl | HBr | H2SO4 | NR | MeOH | HCl | HBr | H2SO4 |
| 1 | 1260 | 1450 | 1150 | 814 | 923 | 15 | 9 | 10 | 9 | 8 | 529 | 750 | 911 | 1331 | 1282 |
| 2 | 11370 | 14400 | 15780 | 8500 | 10500 | 6 | 4 | 3 | 4 | 3 | 147 | 194 | 190 | 326 | 277 |
| 3 | 10690 | 32100 | 14100 | 10880 | 14020 | 5 | 3 | 3 | 3 | 3 | 187 | 101 | 220 | 280 | 258 |
| 4 | 991 | 1930 | 1300 | 777 | 563 | 18 | 10 | 11 | 11 | 12 | 561 | 496 | 679 | 1162 | 1511 |
| 5 | 929 | 1000 | 1100 | 443 | 441 | 25 | 14 | 16 | 14 | 16 | 431 | 730 | 585 | 1620 | 1425 |
| 6 | 883 | 883 | 693 | 336 | 383 | 33 | 22 | 20 | 21 | 21 | 343 | 523 | 710 | 1389 | 1245 |
| 7 | 186 | 211 | 134 | 85 | 99 | 124 | 78 | 69 | 81 | 79 | 434 | 609 | 1079 | 1456 | 1281 |
| 8 | 307 | 355 | 267 | 103 | 134 | 106 | 69 | 66 | 65 | 62 | 307 | 411 | 564 | 1484 | 1198 |
| 9 | 472 | 453 | 305 | 170 | 200 | 104 | 63 | 63 | 66 | 65 | 204 | 348 | 523 | 888 | 775 |
| 10 | 200 | 224 | 142 | 87 | 93 | 130 | 78 | 81 | 84 | 82 | 385 | 572 | 874 | 1367 | 1309 |
| 11 | 128 | 140 | 88 | 43 | 49 | 235 | 149 | 133 | 155 | 144 | 332 | 478 | 854 | 1502 | 1421 |
| 12 | 200 | 169 | 135 | 67 | 74 | 213 | 129 | 139 | 129 | 133 | 235 | 459 | 533 | 1155 | 1014 |
| 13 | 253 | 306 | 174 | 145 | 144 | 102 | 61 | 59 | 57 | 57 | 388 | 534 | 981 | 1204 | 1224 |
| 14 | 914 | 1100 | 899 | 597 | 603 | 38 | 21 | 24 | 21 | 22 | 288 | 433 | 464 | 816 | 746 |
| 15 | 570 | 556 | 490 | 203 | 227 | 57 | 37 | 37 | 36 | 36 | 308 | 483 | 549 | 1365 | 1228 |
| 16 | 800 | 888 | 722 | 552 | 608 | 39 | 25 | 25 | 24 | 24 | 321 | 455 | 546 | 740 | 676 |
| 17 | 8761 | 9020 | 7325 | 4488 | 5000 | 8 | 5 | 5 | 5 | 5 | 143 | 241 | 267 | 439 | 415 |
| 18 | 13030 | 13239 | 11562 | 7634 | 8059 | 7 | 4 | 4 | 4 | 4 | 110 | 173 | 206 | 299 | 292 |
| 19 | 12489 | 11100 | 8333 | 5884 | 6128 | 10 | 6 | 5 | 6 | 6 | 83 | 144 | 227 | 285 | 277 |
| 20 | 136 | 144 | 107 | 53 | 65 | 197 | 119 | 128 | 119 | 122 | 373 | 584 | 730 | 1590 | 1258 |

Sulfuric acid was used as a representative acid to test the influence of rinsing step parameters. The rinse solution temperature, acid concentration, and rinsing time were varied to determine the influence of these parameters on sheet resistance. In some embodiments, the reduction in sheet resistance observed after performing acid rinsing on the vapor deposited films occurred rapidly and was not significantly dependent on the rinse solution temperature, acid concentration, and/or rinsing time. The rapid reduction of sheet resistance with increasing rinse time and concentration was observed even for thicker films (>100 nm). The speed with which the change occurred and the ability to significantly lower the film sheet resistance even at low acid concentrations (<0.5 mol L⁻¹) can be beneficial parameters for a potential scaled up process.

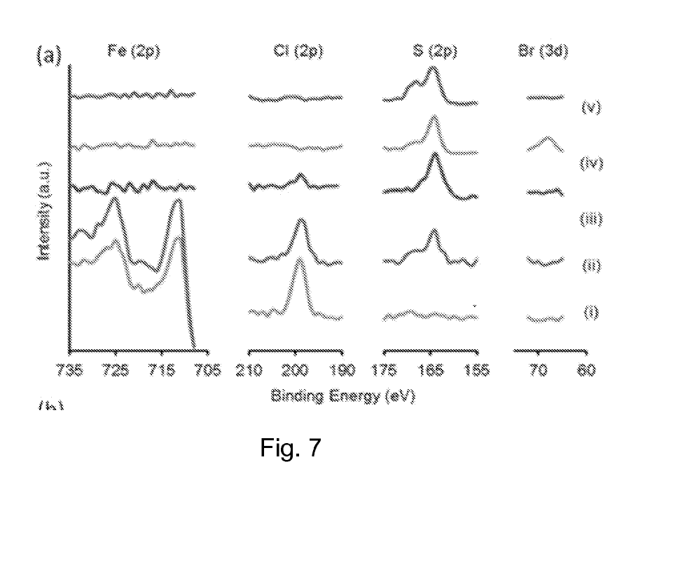

XPS: X-ray photoelectron spectroscopy (XPS) was used to determine the presence or absence of dopant and the presence or absence dopant exchange in unrinsed films, films rinsed in methanol, and films rinsed in each of the three acid solutions. FIG. 7 shows the X-ray photoelectron spectroscopy survey scan of (i) unrinsed, (ii) MeOH rinsed, (iii) 1 M HCl rinsed, (iv) 1 M HBr rinsed, and (v) 1 M H₂SO₄ rinsed PEDOT films on glass comparing regions of interest Fe (2p), Cl (2p), S (2p), and Br (3d). The XPS analysis showed that the residual iron chloride was successfully removed for all three acid rinsing treatments, whereas the methanol rinse left a majority of the iron chloride in the film, as indicated by the Fe (2p) peak. The iron chloride may form hydration complexes with water (equation 1) and dissociate (equation 2) (e.g., see G. Hill and J. Holman, Chemistry in Context, 5 edn., Nelson Thornes, 2000). The low pH of the acidic solutions may enhance the solubility of ferric materials and provides a stable environment for both +2 and +3 Fe compounds. The removed oxidant compounds could be visually observed in the residual rinsing solution by the yellow color arising from a ligand-to-metal charge-transfer (LMCT) band of FeOH(H₂O)₅²⁺.

FeCl₃+6H₂O→Fe(H₂O)₆³⁺+3Cl⁻ (1)

Fe(H₂O)₆³⁺+H₂O→FeOH(H₂O)₅²⁺+H₃O⁺ (2)

The XPS analysis also indicated a dopant exchange occurred for the HBr and H₂SO₄ rinsed films. The intensity of the chlorine peak, Cl (2p), went to zero for the HBr and H₂SO₄ rinsed films. Additionally, a Br (3d) peak appeared for the HBr rinsed film, and the S (2p) formed a double peak corresponding to sulfate doping for the H₂SO₄ rinsed film. Without being bound by theory, it is believed that the exchange process may be driven by the excess of the new dopant anion in the rinse solution and the system reaching equilibrium with the doped polymer chains (e.g., equation 3, where EDOT represents a doped monomer unit).

H⁺Br⁻+EDOT⁺Cl⁻ [symbol] H⁺Cl⁻+EDOT⁺Br⁻ (3)

An XPS depth profiling of a film rinsed with HBr was also performed. The profile scans showed no presence of iron or chlorine in the rinsed film through the entirety of the film thickness, as the appearance of a Si (2p) peak in the bottom curves indicated that the analysis has reached the substrate surface. The presence of the Br (3d) peak through the film also indicated that the dopant exchange occurred throughout the film. The average atomic % ratio of Br to S throughout the HBr rinsed film was 0.3, which amounted to doping of approximately one in every three monomer units (i.e., the theoretical limit for PEDOT:PSS). Films rinsed in pure DI water did not show an improvement in conductivity and the rinse did not remove the residual oxidant.

Morphology: Atomic force microscopy (AFM) and X-ray diffraction were used to determine the roughness and crystallinity of unrinsed films, films rinsed in methanol, and films rinsed in acid solution. Table 4 shows the average surface roughness (Sa) and root-mean square roughness (Sq) of the films after different rinsing conditions, as measured by AFM.

TABLE 4
AFM Roughness Data

| Rinse condition | Sa (nm) | Sq (nm) |
|---|---|---|
| unrinsed | 56.3 | 77.4 |
| MeOH | 7.38 | 18.1 |
| HCl (0.5M) | 4.54 | 5.55 |
| HBr (0.5M) | 2.83 | 3.69 |
| H₂SO₄ (0.5M) | 3.42 | 5.35 |

The unrinsed film and methanol film had the roughest surfaces, because the films had the largest amount of unreacted oxidant remaining in the film. The acid rinsed films had significantly lower roughness. The film rinsed with HBr had the lowest surface roughness. Low surface roughness may be beneficial for polymer electrode applications, because the devices might be less likely to have issues with defects and short circuiting. X-ray diffraction was performed on films before and after methanol and acid rinsing with 1M MeOH, 1M HCl, 1M HBr, and 1M H₂SO₄. The MeOH rinsed film was primarily amorphous, while the acid rinsed films showed a larger broad peak at a 2θ of 26.3° (corresponding to the [020] reflection) indicating an increase in the film crystallinity. The increased peak intensity over the broad background signified partial crystallinity where there exist some crystalline regions embedded in an amorphous matrix. The higher degree of crystallinity was an indication of better inter-chain stacking, which should improve charge transport via chain hopping and therefore enhance film conductivity.

FTIR: Fourier transform infrared spectroscopy (FTIR) was performed on films after various rinsing treatments to determine if the changes observed in the PEDOT sheet resistance were due to structural bond changes. The similarity between the resultant films (e.g., unrinsed, rinsed in MeOH, rinsed in 1 M HCl, rinsed in 1 M HBr, and rinsed in 1 M H₂SO₄) suggested that the changes observed in the PEDOT sheet resistance may be due to dopant and morphology affects rather than significant structural bond changes, such as increased conjugation length.

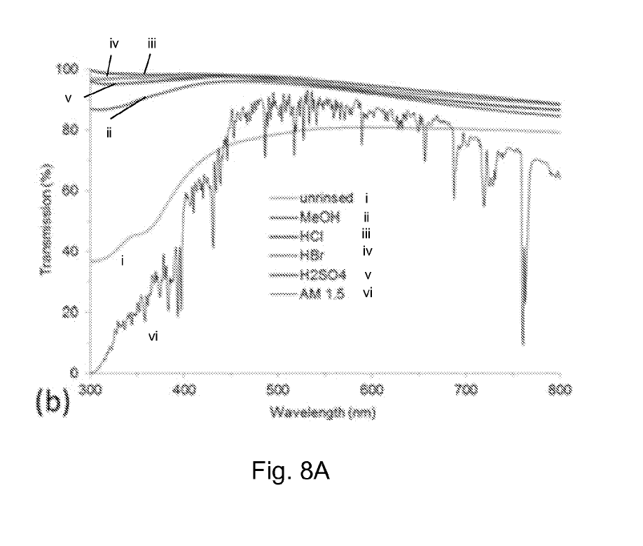

UV-Vis spectroscopy: UV-Vis spectroscopy was used to the determine the transmittance of PEDOT films rinsed with MeOH, 2M HCl, 2M HBr, or 2M H₂SO₄ as well as the tradeoff between transmittance at 560 nm and the sheet resistance. FIG. 8A shows the percent transmittance from 300-800 nm of a 15 nm PEDOT film for each rinsing condition. The black line is for reference and shows the AM1.5 solar spectrum. The unrinsed films, which appeared cloudy over time, had the lowest transmittance while the acid rinsed films had the highest transmittance. The increased transparency of the films after rinsing may be primarily due to the removal of the light-absorbing Fe-species in the residual oxidant.

The transmittance at 560 nm was used to determine the balance between transmittance and sheet resistance. FIG. 8B shows the balance between transmittance and sheet resistance for films after different rinsing conditions. In FIG. 8B, the data points represent experimental data and the solid lines are fit to the following equation relating transmittance (T) and sheet resistance (Rₛₕ):

$$T = {( 1 + \frac{{Z}_{0}}{2 {R}_{sh}} \frac{{σ}_{op}}{{σ}_{dc}} )}^{- 2}$$

Z₀=377Ω is the impedance of free space and σₒₚ and σ_{dc} are the optical and dc conductivities, respectively. The dashed black line is representative for traditional metal oxide electrodes, corresponding to σ_{dc}/σₒₚ=35. The standard industry value for transparent oxide conductors, such as indium tin oxide (ITO), is σ_{dc}/σₒₚ>35. With decreasing sheet resistance for approximately the same transmittance values, the σ_{dc}σₒₚ value increased from ˜4 for the methanol rinsed films to ˜6, 10, and 12 for the HCl, H₂SO₄, and HBr rinsed films, respectively, as shown in FIG. 8B.

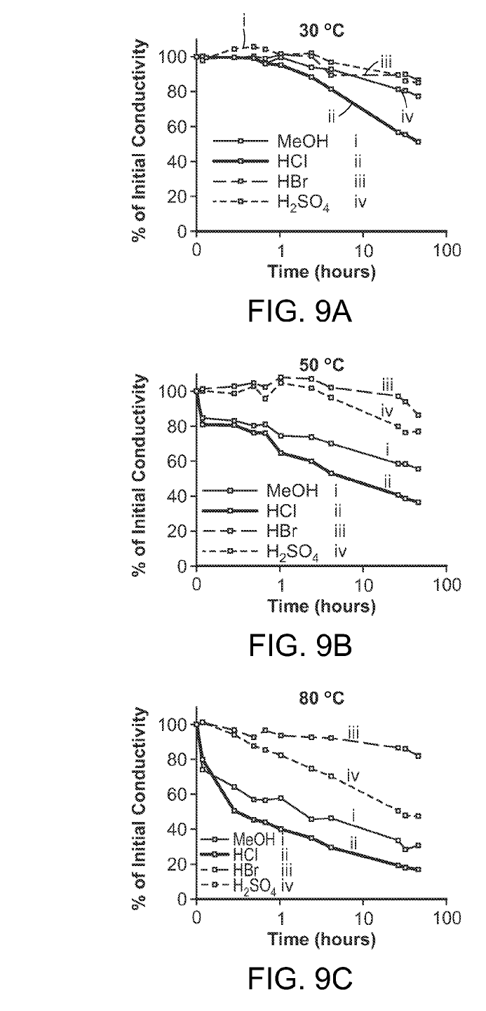

Stability: In some embodiments, another consideration for polymer electrode materials is film stability. To accelerate film degradation, films were heated in air at various temperatures and measured over time for changes in conductivity. FIGS. 9A-C shows the changes in conductivity over a span of 48 hours at 30° C., 50° C., and 80° C. for films following different rinsing conditions.

For each temperature, the HCl rinsed films had the fastest decrease in conductivity, while the HBr and H₂SO₄ films had the slowest losses. The rate of conductivity loss increased with increasing temperature. The films with the smaller, more volatile dopant (e.g., Cl⁻) showed a more rapid decrease in conductivity than the films with heavier dopant molecules. Without being bound by theory, it is believed that the size of the dopant molecules may have an impact on conductivity loss over time. Two known mechanisms of PEDOT degradation are exposure to oxygen and water vapor. Shrinking conductive regions with increased heating over time has also been shown as a thermal degradation mechanism for PEDOT:PSS. One non-limiting explanation for the enhanced stability seen for the acid rinsed films may be tighter chain packing, which may provide a better barrier to the atmosphere. The removal of the excess oxidant, which is hygroscopic, may also reduce water content within the films. The size and reactivity of the dopant molecules may play a role in the film degradation and conductivity loss over time as well.

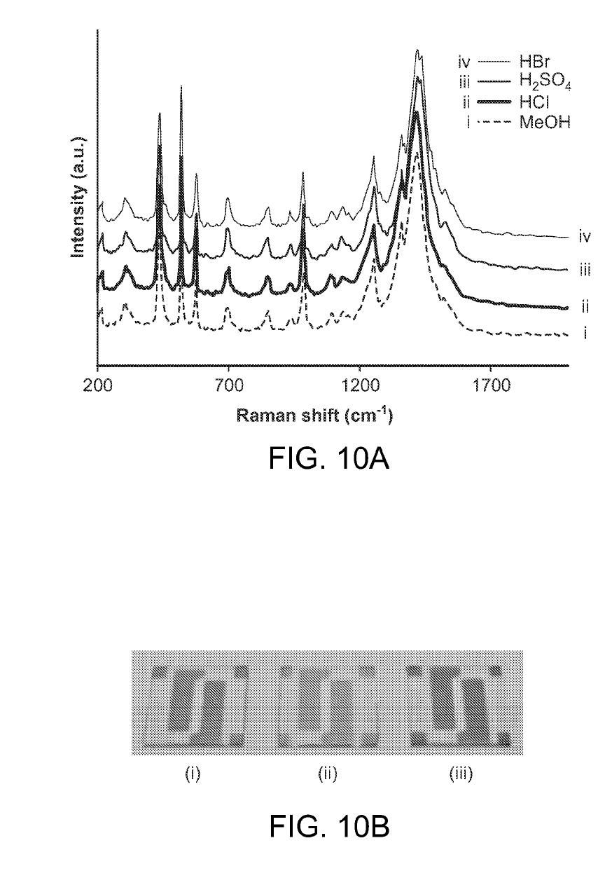

Raman Spectroscopy: Raman spectroscopy was used to determine the degree of doping across films of different rinse conditions after rinsing and after an aging process. FIG. 10A shows the Raman spectra for the films after the different rinsing conditions: MeOH, 1 M HCl, 1 M HBr, and 1 M H₂SO₄. The intensity of the peak at 1259 cm⁻¹, corresponding to C_{α}=C_{α}′ inter-ring stretching, was slightly larger for the HBr and H₂SO₄ rinsed films indicating a quinoid structure. The intensity of the peak height at 1367 cm⁻¹, corresponding to C_{β}-C_{β} stretching, was lower for the more conductive (HBr and H₂SO₄ rinsed) films, also suggesting stabilization of the quinoid structure. In the peak at 1420 cm⁻¹, corresponding to the symmetric C_{α}=C_{β} stretching band, broadening and right shifting for the films with lower sheet resistance (i.e., the HBr and H₂SO₄ rinsed films) were observed. The right shift corresponded to a shift toward the doped state of PEDOT, the shift towards higher wave numbers may be explained by a shift toward a higher degree of doping. These fitted peaks showed that the ratio between the doped versus undoped peaks was much larger for the higher conductivity film.

Raman spectroscopy was performed on rinsed films before and after an accelerated aging experiment (e.g., heating at ambient conditions for 100 hours at 100° C.). With the decrease in film conductivity after aging, there was a corresponding left shift in the Raman spectra at the 1420 cm⁻¹ C_{α}=C_{β} stretching peak toward the undoped state of PEDOT from the original doped state as shown in FIG. 10A. This shift supported the theory that conductivity degradation during the aging process can be a result of dopant loss. Photographs of thick patterned PEDOT films (i) unrinsed (ii) rinsed in 0.5 M HCl, and (iii) rinsed in 0.5 M HCl and heated for 175 hours at 100° C. are shown in FIG. 10B. A color change (i.e., blue to purple shift) was observed for the film rinsed in HCl, which underwent the largest, most rapid decrease in conductivity. The shift from blue (ii) to purple (iii) was similar to the shift observed when chemically reducing/dedoping PEDOT film.

Conclusion:

It was demonstrated that rinsing oCVD polymerized PEDOT films in an acid solution can have many benefits on the film properties including lowering sheet resistance. The residual reacted and unreacted oxidant, FeCl₃, was removed from the film which contributed to increased optical transmittance and lower film roughness. A dopant exchange occurred with the acid anions leading to a higher degree of doping and enhanced film stability. These improvements to the film properties may be useful for implementing oCVD polymer layers into optoelectronic device application, amongst other applications.

### EXPERIMENTAL

### Film Preparation and Rinsing

Glass and silicon substrates were cleaned by sequential sonication in acetone, deionized water, and isopropyl alcohol, followed by 30 second of oxygen plasma treatment. The PEDOT films were synthesized by oxidative chemical vapour deposition as is known in the art (e.g., see W. E. Tenhaeff and K. K. Gleason, Advanced Functional Materials, 2008, 18, 979-992). In short, glass and silicon substrates were simultaneously exposed to vapours of 3,4-ethylenedioxythiophene

(EDOT) monomer (Aldrich 97%) metered at ˜5 sccm and FeCl₃ oxidant (Sigma Aldrich, 99.99%) controllably evaporated from a crucible resistively heated from 100-180° C. at a constant heating rate of 1.5° C. min⁻¹. For each comparison across rinsing conditions all samples were used from a single deposition. Process conditions were held the same across all depositions (chamber pressure ˜0.1 mTorr, substrate temperature=150° C.). Run time was varied to create films of different thicknesses. Hydrochloric acid (HCl) (Aldrich 37%), hydrobromic acid (HBr) (Aldrich 48%), and sulphuric acid (H₂SO₄) (Aldrich 98%) were diluted with deionized H₂O to make rinsing solutions ranging from 0.01-5 mol L⁻¹. With the exception of experiments investigating acid rinse concentration and time, films were rinsed for 5 minutes in acid followed by drying for 30 minutes before a final rinse in MeOH. All rinsing and drying steps were done in ambient conditions.

### Characterization

XPS and XRD were performed at the Cornell Center for Materials Research (CCMR). XPS depth profiling was done at a speed of ˜10 nm min⁻¹. UV-Vis was performed using a Cary 5000 over a wavelength range of 200-2000 nm. FTIR was performed on a Nexus 870 FT-IR ESP. Raman spectroscopy was performed on a Horiba HR800 using a 784.399 nm laser. Roughness data was collected using tapping mode AFM (Agilent Technologies) over 1 μm and 10 μm square scans. Film sheet resistance was measured using a Jandel 4-pt probe. Averages were calculated over 10 point measurements. Film thicknesses were measured using a Dektak profilometer. Average values were taken over 10 line scans.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A photovoltaic cell, comprising:
a first electrode;
a second electrode;
a photoactive material positioned between the first electrode and the second electrode; and
a substrate, wherein the second electrode is positioned between the photoactive material and the substrate,
wherein the first electrode is formed by or formable by oxidative chemical vapor deposition.

2. A photovoltaic cell, comprising:
a first electrode;
a second electrode;
a photoactive material positioned between the first electrode and the second electrode; and
a substrate, wherein the second electrode is positioned between the photoactive material and the substrate,
wherein the first electrode is formed by or formable by polymerization of vapor phase precursors.

3. A method of forming a photovoltaic cell, comprising:
providing a substrate;
depositing a second electrode on the substrate;
optionally depositing a second electrode buffer material on the second electrode;
depositing a photoactive material on the second electrode or the optionally deposited second electrode buffer material;
optionally depositing a first electrode buffer material on the photoactive material; and
depositing, via oxidative chemical vapor deposition, a first electrode on the photoactive material or the optionally deposited first electrode buffer material.

4. The photovoltaic cell as in claim 1, wherein the first electrode comprises a conductive polymer.

5. The photovoltaic cell as in claim 5, wherein the conductive polymer comprises poly(3,4-ethylenedioxythiophene).

6. The method as in claim 3, wherein the oxidative chemical vapor deposition comprises:
providing a vapor-phase monomer species and a vapor-phase oxidizing agent to produce a vapor comprising a conductive polymer precursor; and
contacting the vapor with the surface of the photoactive material or optional first electrode buffer material to form a transparent or semi-transparent electrode on top of the device.

7. The method as in claim 6, wherein the oxidizing agent is CuCl₂, FeCl₃, FeBr₃, I₂, POBr₃, GeCl₄, SbI₃, Br₂, SbF₅, SbCl₅, TiCl₁, POCl₃, SO₂Cl₂, CrO₂Cl₂, S₂Cl, O(CH₃)₃SbCl₆, VCl₄, VOCl₃, BF₃, (CH₂)₃)₂O.BF₃, (C₂H₅)₃O(BF₄), or BF₃.O(C₂H₅)₂.

8. (canceled)

9. The method as in claim 6, wherein the monomer species is 3,4-ethylenedioxythiophene.

10. The photovoltaic cell as in claim 1, wherein the second electrode comprises a metal.

11. The photovoltaic cell as in claim 11, wherein the metal is silver, aluminum, calcium, or gold.

12. The photovoltaic cell as in claim 1, wherein the photoactive material comprises an electron-accepting material and an electron-donating material.

13. The method as in claim 3, wherein the electron-accepting material is associated with the optionally present second electrode buffer material or the second electrode and the electron-donating material, and the electron-donating material is associated with the optionally present first electrode buffer material or the first electrode and the electron-accepting material.

14. The method as in claim 13, wherein the electron-accepting material comprises C₆₀,3,4,9,10-perylene tetracarboxylic bisbenzimidazole, TiO₂, or ZnO.

15. The method as in claim 13, wherein the electron-donating material comprises a phthalocyanine, a merocyanine dye, or an optionally substituted conjugated polymer based on polythiophene.

16. The method as in claim 13, wherein the electron-donating material comprises tetraphenyldibenzoperiflanthene, copper phthalocyanine, chloroaluminum phthalocyanine, or tin phthalocyanine.

17. The method as in claim 3, wherein the optionally present first electrode buffer material comprises a metal oxide.

18-19. (canceled)

20. The photovoltaic cell as in claim 1, wherein the first electrode is transparent or substantially transparent.

21. The photovoltaic cell as in claim 1, wherein the substrate is opaque or substantially opaque.

22. The photovoltaic cell as in claim 1, wherein the substrate is flexible.

23. The photovoltaic cell as in claim 1, wherein the photovoltaic cell is an inverted photovoltaic cell.

24-29. (canceled)
